(19) United States
(12) Patent Application Publication
(10) Pub. No.: US 2025/0199403 A1
(43) Pub. Date: Jun. 19, 2025

(54) COMPOSITION INCLUDING ALKALINE-SOLUBLE POLYMER AND COLORANT

(71) Applicant: Merck Patent GmbH, Darmstadt (DE)

(72) Inventors: Seishi Shibayama, Kakegawa-Shi (JP); Daishi Yokoyama, Kakegawa-Shi (JP); Atsuko Noya, Kakegawa-Shi (JP)

(21) Appl. No.: 19/062,360

(22) Filed: Feb. 25, 2025

Related U.S. Application Data
(63) Continuation of application No. PCT/EP2023/073077, filed on Aug. 23, 2023.

(30) Foreign Application Priority Data
Aug. 26, 2022 (EP) 22192493.9

(51) Int. Cl. G03F 7/038; C08L 81/02; G02B 1/04; G02B 5/22

(52) U.S. Cl. CPC G03F 7/038; C08L 81/02; G02B 1/04; G02B 5/22

(57) ABSTRACT

A composition includes an alkaline-soluble polymer that includes an ethylenic double bond, and a colorant.

### CROSS-REFERENCE TO RELATED APPLICATIONS

This application is a Continuation under 35 USC § 111 (a) of International Patent Application No. PCT/EP2023/073077 filed Aug. 23, 2023, which claims priority to EP Application Serial No. 22192493.9 filed Aug. 26, 2022. The entire contents of these applications are incorporated herein by reference in their entirety.

### FIELD OF THE INVENTION

The present invention relates to a composition that includes an alkaline-soluble polymer and a colorant. The present invention further relates to a method for fabricating a cured layer, a layer, a light converting device, an optical device, use of the device, use of the light converting device and a method of fabricating an optical device.

### BACKGROUND ART

JP 2022-33154 A and JP 2021-113977 A (Toray) describe a polysiloxane-based resin composition containing polysiloxane, white pigment, and an organic metal compound (working examples).

JP 2021-161401 A (Toray) indicates a polysiloxane based resin composition that includes a photo radical generator, polysiloxane, and a polymer of (meth)acryl polymer or cardo-type polymer as claimed in claim 1.

However, the inventors newly have found that there are still one or more considerable problems for which improvement is desired, as listed below: enabling development with a low-concentration alkaline developer, preferably in a shorter development time and/or achieving both reactivity and storage stability of the composition; realizing high sensitivity of the composition lowering exposure energy and exposure time; improving the structure of a patterned cured film (bank structure), especially improving the bottom side structure of a patterned cured film; providing improved curability of the bottom side of the coated composition; realizing improved reflection and/or high optical density (OD) of the cured film, especially realizing improved reflection and/or high OD of the cured film having white and black pigments (grey colored bank).

### SUMMARY OF THE INVENTION

The present inventors have surprisingly found that one or more of the above described technical problems can be solved by the features as defined in the claims.

Namely, one or more of the above problems are solved by a composition, preferably a photocurable composition, and preferably a composition that does not include any polysiloxane. The composition includes at least:
i. an alkaline-soluble polymer that includes an ethylenic double bond;
   and
ii. a colorant.

In another aspect, the present invention also relates to a method for fabricating a cured layer comprising at least the following steps:
(Xi) providing the composition of the present invention onto a layer or onto a substrate to form a coated layer; and
(Xii) baking a coated layer to obtain a cured layer.

In another aspect, the present invention relates to a layer obtained or obtainable from the method of the present invention.

In another aspect, the present invention also relates to a layer comprising at least:
i. a polymer (A) derived or derivable from an alkaline-soluble polymer containing an ethylenic double bond;
   and
ii. a colorant.

In another aspect, the present invention further relates to a light converting device comprising at least the layer of the present invention.

In another aspect, the present invention also relates to an optical device comprising at least the layer of the present invention or a light converting device of the present invention.

In another aspect, the present invention further relates to a use of the composition of the present invention, or the layer of the present invention in a fabrication process of a light converting device.

In another aspect, the present invention further relates to a use of the light converting device of the present invention in a fabrication process of an optical device.

In another aspect, the present invention further relates to a method of fabricating an optical device comprising at least;
providing the light converting device of the present invention into an optical device.

Further advantages of the present invention will become evident from the following detailed description.

### DETAILED DESCRIPTION OF THE INVENTION

In the present specification, symbols, units, abbreviations, and terms have the following meanings unless otherwise specified.

In the present specification, unless otherwise specifically mentioned, the singular form includes the plural form and “one” or “that” means “at least one”. In the present specification, unless otherwise specifically mentioned, an element of a concept can be expressed by a plurality of species, and when the amount (for example, mass % or mol %) is described, it means sum of the plurality of species. “And/or” includes a combination of all elements and also includes single use of the element.

In the present specification, when a numerical range is indicated using “to” or “-”, it includes both endpoints and units thereof are common. For example, 5 to 25 mol % means 5 mol % or more and 25 mol % or less.

In the present specification, the hydrocarbon means one including carbon and hydrogen, and optionally including oxygen or nitrogen. The hydrocarbyl group means a monovalent or divalent or higher valent hydrocarbon. In the present specification, the aliphatic hydrocarbon means a linear, branched or cyclic aliphatic hydrocarbon, and the aliphatic hydrocarbon group means a monovalent or divalent or higher valent aliphatic hydrocarbon. The aromatic hydrocarbon means a hydrocarbon comprising an aromatic ring which may optionally not only comprise an aliphatic hydrocarbon group as a substituent but also be condensed with an alicycle. The aromatic hydrocarbon group means a monovalent or divalent or higher valent aromatic hydrocarbon. Further, the aromatic ring means a hydrocarbon comprising a conjugated unsaturated ring structure, and the alicycle means a hydrocarbon having a ring structure but comprising no conjugated unsaturated ring structure.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain.

In the present specification, the aryl means a group obtained by removing any one hydrogen from an aromatic hydrocarbon. The alkylene means a group obtained by removing any two hydrogens from a linear or branched, saturated hydrocarbon. The arylene means a hydrocarbon group obtained by removing any two hydrogens from an aromatic hydrocarbon.

In the present specification, the descriptions such as “C_{x-y}”, “Cₓ-C_{y}” and “Cₓ” mean the number of carbons in the molecule or substituent group. For example, C₁₋₆ alkyl means alkyl having 1 to 6 carbons (such as methyl, ethyl, propyl, butyl, pentyl and hexyl). Further, the fluoroalkyl as used in the present specification refers to one in which one or more hydrogen in alkyl is replaced with fluorine, and the fluoroaryl is one in which one or more hydrogen in aryl are replaced with fluorine.

In the present specification, when polymer has a plural types of repeating units, these repeating units copolymerize. These copolymerization are any of alternating copolymerization, random copolymerization, block copolymerization, graft copolymerization, or a mixture of any of these.

In the present specification, “%” represents mass % and “ratio” represents ratio by mass.

According to the present invention, the composition, preferably it is being of a photocurable composition, preferably said composition does not contain any polysiloxane, comprising at least, essentially consisting of or consisting of;
i. an alkaline-soluble polymer containing an ethylenic double bond;
   and
ii) a colorant.

### Alkaline-Soluble Polymer

The composition according to the present invention comprises an alkali-soluble polymer containing an ethylenic double bond.

Preferably the solid acid value of the alkaline polymer is in the range from 30 to 160 mgKOH/g, more preferably from 50 to 150 mg KOH/g, even more preferably from 60 to 80 mg KOH/g from the viewpoint of enabling development with a low-concentration alkaline developer, preferably in a shorter development time, and achieving both reactivity and storage stability. For examples, 2-Propenoic acid, 2-methyl-, polymer with 2-hydroxyethyl 2-methyl-2-propenoate, 2-isocyanatoethyl 2-propenoate and methyl 2-methyl-2-propenoate (C6 H10 O3. C6 H7 NO3. C5 H8O2. C4 H6O2)×(CAS Registry Number 1615232-03-05) can be used preferably to form the polymer.

In a preferable embodiment of the present invention, the weight-average molecular weight of said alkaline-soluble polymer is in the range from 1,000 to 100,000, more preferably it is from 1,200 to 30,000, even more preferably it is from 3000 to 8000 from the view point of desirable viscosity, reactivity, developing ability, easy handling. Here, the weight average molecular weight is a weight average molecular weight in terms of polystyrene according to gel permeation chromatography.

Such alkaline-soluble polymer is available for example as described in JP 2016-69400 A (Natoko), ACA series from DAICELallnex co., such as (ACA) Z200M, (ACA) Z250, (ACA) Z251, (ACA) Z254F, (ACA) Z300, (ACA) Z320.

Preferably said alkali-soluble polymer is polymer containing an acryloyl group. Thus, preferably said alkaline-soluble polymer is a (meth)acrylate polymer, more preferably it is a methacrylate polymer, an acrylate polymer or a combination of thereof, even more preferably the polymer material is an acrylate polymer.

The alkali-soluble polymer used in the present invention can have a carboxyl group. By having a carboxyl group, the solubility of the alkali-soluble polymer in a low-concentration developer can be improved.

According to the present invention, the term “Alkali-soluble polymer” means a polymer soluable in 2.38% TMAH aqueous solution at 23.0±0.1° C.

(meth)acrylate Polymer

Here, the term “(meth)acrylate” is a general term for an acrylate and a methacrylate.

According to the present invention, when a low-concentration developer is used and/or low curing temperature is applied, it is preferable to use one or more of (meth)acrylate polymers.

The alkali-soluble polymer used in the present invention can be selected from generally used methacrylate polymer, an acrylate polymer or a combination of thereof, more preferably it is an acrylic polymer, for example, polyacrylic acid, polymethacrylic acid, polyalkyl acrylate, polyalkyl methacrylate, and the like. The acrylic polymer used in the present invention preferably comprises a repeating unit containing an acryloyl group, and also preferably further comprises a repeating unit containing a carboxyl group.

Although the repeating unit containing a carboxyl group is not particularly limited as long as it is a repeating unit containing a carboxyl group at its side chain, a repeating unit derived from an unsaturated carboxylic acid, an unsaturated carboxylic anhydride or a mixture thereof is preferable.

Further, it is preferable that the above-described polymer contains a repeating unit containing a hydroxyl group, which is derived from a hydroxyl group-containing unsaturated monomer.

Further, a (patterned) cured film is formed by applying the composition according to the present invention onto a substrate, imagewise exposure, and development. At this time, it is necessary that a difference in solubility occurs between the exposed area and the unexposed area, and the coating film in the unexposed area should have a certain or more solubility in a developer. For example, it is considered that a pattern can be formed by exposure and development if dissolution rate of the coating film after pre-baked, in a 2.38% tetramethylammonium hydroxide (hereinafter sometimes referred to as TMAH) aqueous solution (hereinafter sometimes referred to as alkali dissolution rate or ADR, which is described later in detail) is 50 Å/sec or more. However, since the required solubility varies depending on the film thickness of the cured film to be formed and the development conditions, the alkali-soluble polymer should be appropriately selected according to the development conditions. Although it varies depending on the type and addition amount of the photosensitizer or the silanol catalyst contained in the composition, for example, if the film thickness is 0.1 to 100 μm (1,000 to 1,000,000 Å), the dissolution rate in a 2.38% TMAH aqueous solution is preferably 50 to 20,000 Å/sec, and more preferably 100 to 10,000 Å/sec.

### Thiol Containing Polyfunctional Chemical Compound

According to the present invention, in a preferable embodiment, said composition further comprises a thiol containing polyfunctional chemical compound. Preferably said thiol containing polyfunctional chemical compound contains a pentaerythritol structure.

In a more preferable embodiment, said thiol containing polyfunctional chemical compound is represented by following chemical formula (I^{x})

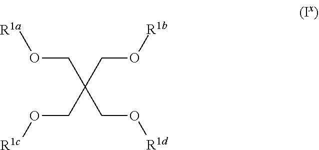

wherein
R^{1a}, R^{1b}, R^{1c} and Rid are, independently of each other, selected from a hydrogen atom, alkyl chain having 1 to 10 carbon atoms, cyclo group having 3 to 10 carbon atoms cyclo-alkyl group having 4 to 10 carbon atoms, aryl group having 3 to 10 carbon atoms or an alkoxy group having 1 to 10 carbon atoms, where at least one H atom is replaced with SH group, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂, wherein at least one of R^{1a}, R^{1b}, R^{1c} and Rid is not a hydrogen atom, preferably at least two of R^{1a}, R^{1b}, R^{1c} and R^{1d} are not a hydrogen atom, more preferably at least R^{1a}, R^{1b}, R^{1c} are not a hydrogen atom.

As the thiol containing polyfunctional chemical compound, publicly available one can be used. Examples of such thiol containing polyfunctional chemical compounds may include bifunctional thiols such as 1,4-bis(3-mercaptobutyryloxy) butane, 1,3,5-tris (2-(sulfanylbutanoyloxy) ethyl), tris-[(3-mercaptopropionyloxy)-ethyl-]-isocyanulate, trimethylolpropanetris (3-mercaptopropionate), dipentaerythritol hexakis (3-mercaptopropionate), trimethylolpropanetris (3-mercaptobutyrate), trimethylol-ethanthetris (3-mercaptobutylate) and other three-functional thiols such as 2-hydroxymethyl-2-methyl-1,3-propanediol Tris-(3-mercaptopropionate), Trimethylolpropane Tris (3-mercaptobutyrate) (Karenz MT-TPMB (Trademark)), pentaerythritol tetrakis(3-sulfanylbutanoate), trimethylolpropane tris(3-mercaptopropionate) (TMMP-LV; SC chem.), four-functional thiols such as pentaerythyritol tetrakis(3-mercaptopropionate) (PEMP-LV: SC chem.), Pentaerythritol tetrakis(3-mercaptobutyrate) (Karenz MT-PE-1 (Trademark)). Among them, preferable one as the thiol containing polyfunctional chemical compound contains a pentaerythritol structure like Trimethylolpropane Tris(3-mercaptobutyrate) (Karenz MT-TPMB (Trademark)), Pentaerythritol tetrakis(3-mercaptobutyrate) (Karenz MT-PE-1 (Trademark)) from the view point of high sensitivity to lowering exposure energy and exposure time.

Chemical Compound Containing at Least Two (meth)acryloyloxy Groups

In a preferable embodiment of the present invention, the composition further comprises a chemical compound containing at least two (meth)acryloyloxy groups.

Preferably said at least two (meth)acryloyloxy groups are two or more acryloyloxy groups, methacryloyloxy groups or a combinaiton of these, preferably the total amount of the chemical compound containing said at least two (meth)acryloyloxy groups based on the total amount of the alkaline-soluble polymer is in the range from 5 wt. % to 1,000 wt. %, more preferably from 10 wt. % to 500 wt. %, even more preferably it is from 15 wt. % to 300 wt. % from the viewpoint of compatibility with resin., preferably said chemical compound is a monomer having the molecular weight 2000 or less, more preferably in the range from 2000 to 50, even more preferably from 1000 to 100. Preferably it is relatively smaller than the alkali-soluble polymer from the viewpoint of reactivity.

Here, the term “(meth)acryloyloxy group” is a general term for the acryloyloxy group and the methacryloyloxy group. This compound is a compound that can form a crosslinked structure by reacting with the alkali-soluble polymer. Here, in order to form a crosslinked structure, a compound containing two or more acryloyloxy groups or methacryloyloxy groups, which are reactive groups, is needed, and in order to form a higher-order crosslinked structure, it preferably contains three or more acryloyloxy groups or methacryloyloxy groups.

Further, the (meth)acryloyloxy group-containing compounds can be used alone or in combination of two or more.

Preferably said chemical compound containing at least two (meth)acryloyloxy groups, is a poly acrylate monomer having at least three (meth)acryloyloxy groups, more preferably it is a poly acrylate monomer selected from one or more member of the group consisting of a poly acrylate monomer having three (meth)acryloyloxy groups, a poly acrylate monomer having four (meth)acryloyloxy groups, a poly acrylate monomer having five (meth)acryloyloxy groups, a poly acrylate monomer having six (meth)acryloyloxy groups, even more preferably it is a poly acrylate monomer having five (meth)acryloyloxy groups, a poly acrylate monomer having six (meth)acryloyloxy groups or a mixture of thereof, preferably said poly acrylate monomer having three (meth)acryloyloxy groups is selected from one or more member of the group consisting of trimethylolpropane triacrylate, trimethylolpropaneethoxy triacrylate, trimethylolpropanepropoxy triacrylate, glycerinpropoxy triacrylate, pentaerythritol triacrylates;
preferably said poly acrylate monomer having four (meth)acryloyloxy groups is selected from one or more member of the group consisting of pentaerythritol tetraacrylates, ditrimethylolpropane tetraacrylate, pentaerythritolehoxy tetraacrylates;
preferably said poly acrylate monomer having five (meth)acryloyloxy groups is dipentaerythritol hexaacrylates, preferably said poly acrylate monomer having six (meth)acryloyloxy groups is dipentaerythritol pentaacrylate,
the most preferably said chemical compound is dipentaerythritol hexaacrylates, dipentaerythritol pentaacrylate or a mixture of thereof.

### Surfactant

Further, the composition according to the present invention can optionally comprise a surfactant. Preferably said surfactant is a halogen containing surfactant, preferably said surfactant has at least one crosslinking group, preferably said halogen is selected from fluorine, chlorine, bromine and iodine, more preferably said halogen is fluorine, more preferably said surfactant is a halogen containing surfactant having at least one crosslinking group, even more preferably it is a fluorine containing surfactant having at least one crosslinking group, furthermore preferably said surfactant is a fluorine containing surfactant having at least one crosslinking group containing a perfluoroalkyl group or perfluoro alkylene group;
preferably the total amount of the surfactant is in the range from 0.0001 to 3 wt. %, more preferably from 0.001 to 1 wt. %, even more preferably from 0.01 to 0.6 wt. %, furthermore preferably from 0.1 to 0.3 wt % based on the total solid contents of the composition.

Said crosslinking group of the surfactant is for examples, an epoxy group or an ethylenically unsaturated group. Preferably it is an ethylenically unsaturated group.

Preferably, the surfactant of the present invention contains a perfluoroalkyl group or perfluoroalkylene group or the surfactant of the present invention may contain both a perfluoroalkyl group and a perfluoroalkylene (ester) group from the view point of realizing oil repellency at the top surface of the coated (cured) layer.

As the perfluoroalkyl group, for examples, perfluoro-butyl group, perfluoro-hexyl group, perfluoro-octyl group or a combination of any of them can be used.

As the perfluoroalkylene (ester) group, for examples, —CF₂—O—, —(CF₂)₂—O—, —(CF₂)₃—O—, —CF₂—C(CF₃)—O— or —C(CF₃)—CF₂—O—, or a divalent group having a repeating unit of —CF₂—O—, —(CF₂)₂—O—, —(CF₂)₃—O—, —CF₂—C(CF₃)—O— or —C(CF₃)—CF₂—O— can be used preferably.

Examples of the surfactant is for examples, acryl copolymer having epoxy group and perfluoroalkyl group, acryl copolymer having epoxy group and perfluoroalkylene ester group, acryl copolymer having ethylenically unsaturated group and perfluoroalkyl group, acryl copolymer having ethylenically unsaturated group and perfluoroalkylene ester group,

Epoxy (meth)acrylate polymer having epoxy group and perfluoroalkyl group, epoxy (meth)acrylate polymer having epoxy group and perfluoroalkylene ester group, epoxy (meth)acrylate polymer having ethylenically unsaturated group and perfluoroalkyl group, epoxy (meth)acrylate polymer having ethylenically unsaturated group and perfluoroalkylene ester group.

More preferably acryl copolymer having ethylenically unsaturated group and perfluoroalkyl group, acryl copolymer having ethylenically unsaturated group and perfluoroalkylene ester group is used.

Even more preferably, acryl copolymer having ethylenically unsaturated group and perfluoroalkylene ester group is used.

As such surfactants, publicly available one can be used.

For example of acryl copolymer having ethylenically unsaturated group and perfluoroalkylene ester group, MEGAFACE RS Series (DIC), especially RS-72A, RS-78, RS-90 can be used preferably.

The surfactant is added for the purpose of improving coating properties, developability, realizing improved hydrophobic bank surface, and/or realizing improved oil-repellent bank surface.

### Colorant

According to the present invention, the composition comprises a colorant, preferably the total amount of said colorant is 3 to 80 wt. %, preferably 5 to 50 wt. % based on the total amount of the solid contents of the composition.

Preferably said colorant is a 1^{st} colorant selected from an organic colorant and/or an inorganic colorant, more preferably it is a black colorant selected from an organic black pigment and/or inorganic black pigment or a white colorant selected from an organic white pigment and/or inorganic white pigment, furthermore preferably it is a black colorant selected from an organic black pigment and/or inorganic black pigment, even more preferably it is a inorganic black pigment, particularly preferably said inorganic black pigment is zirconium nitride or a tinatnina oxide, which may be coated by a polymer and/or inorganic layer.

As the colorant used in the present invention (preferably black colorant), either an inorganic pigment or an organic pigment, or a combination of two or more pigments can be used as long as it satisfies the required absorbance.

When an organic type black colorant is used in the bank, it is preferable to combine two or more organic pigments to obtain a black pigment. For examples, by mixing respective colors of red, green and blue organic pigments, a black color pigment can be obtained.

The colorant used in the present invention can be used in combination with a dispersant. As the dispersant, an organic compound-based dispersant such as a polymer dispersant described, for example, in JP-A 2004-292672 can be used.

In a preferable embodient of the present invention, the composition further comprises another colorant different from the 1^{st} colorant.

Preferably said another colorant is a 2^{nd} colorant selected from an organic colorant and/or an inorganic colorant, more preferably it is a black colorant selected from an organic black pigment and/or inorganic black pigment or a white colorant selected from an organic white pigment and/or inorganic white pigment, even more preferably it is a white colorant selected from an organic white pigment and/or inorganic white pigment, furthermore preferably it is an inorganic white colorant.

Thus, in a further preferable embodiment of the present invention, the composition comprises the 1^{st} colorant and the 2^{nd} colorant, wherein the 1^{st} colorant is a black pigment and the 2^{nd} colorant is a white pigment to realize grey colored composition and grey colored patterned bank.

As the 1^{st} colorant and the 2^{nd} colorant, publicly available one can be used preferably.

In some embodiments of the present invention, the composition further comprises 3^{rd} colorant different from the 1^{st} colorant and the 2^{nd} colorant.

Preferably said 3^{rd} colorant is an inorganic black pigment, more preferably said colorant is an inorganic black pigment selected from zirconium nitride and/or a titanium oxide, which may be coated by a polymer and/or inorganic layer.

In a preferable embodiment of the present invention, the amount of the colorant (the 1^{st} colorant) is in the range from 0.1 to 50 wt % based on the total weight of the alkaline-soluble polymer of the composition, preferably it is from 1 to 30 wt %, more preferably from 1.5 to 20 wt %, even more preferably from 2.0 to 15 wt % from the view point of smooth surface of the patterned layer (bank), improved OD, improved reflection and/or improved patterned & developed bank structure.

In a preferable embodiment of the present invention, the amount of the another colorant (the 2^{nd} colorant) is in the range from 1 wt % to 400 wt %, preferably from 5 wt % to 300 wt %, more preferably from 10 wt % to 200 wt % based on the total weight of the alkaline-soluble polymer of the composition from the view point of smooth surface of the patterned layer (bank), improved OD, and/or improved reflection. By optimizing the amount of the another colorant, pattern structure of the cured & developed film (bank) can also be improved.

In a preferable embodiment of the present invention, the ratio of the colorant (the 1^{st} colorant) to the another colorant (the 2^{nd} colorant) is in the range from 0.0001 to 50 from the view point of smooth surface of the patterned layer (bank), improved OD, and/or improved reflection.

### Solvent

In a preferred embodiment of the present invention, the composition further comprises a solvent.

The type solvent is not particularly limited and publicly available solvents can be used as long as it can uniformly dissolve or disperse the above-described alkali-soluble polymer, the polymerization initiator and a chemical compound containing at least two (meth)acryloyloxy groups.

Preferably said solvent is selected from one or more of the members of the group consisting of ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether and propylene glycol monoethyl ether; propylene glycol alkyl ether acetates such as PGMEA, propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol and glycerin; esters, such as ethyl lactate, ethyl 3-ethoxypropionate, methyl 3-methoxypropionate; and cyclic esters, such as γ-butyrolactone, more preferably said solvent is a combination of propylene glycol alkyl ether acetates or esters, and cyclic esters, such as γ-butyrolactone, preferably the total amount of said solvent based on the total amount of the composition is in the range from 1 wt. % to 99 wt. %, preferably from 5 wt. % to 90 wt. %, even more preferably from 10 wt. % to 80 wt. %, furthermore preferably from 20 wt. % to 70 wt. %.

### Polymerization Initiator

The composition according to the present invention may comprise a polymerization initiator. The polymerization initiator includes a polymerization initiator that generates an acid, a base or a radical by radiation, and a polymerization initiator that generates an acid, a base or a radical by heat.

Thus, in a preferable embodiment of the present invention, the composition further comprises a polymerization initiator. More preferably said polymerization initiator is selected from photo-radical initiators, photo-acid generators or a combination of photo-radical initiator and photo-acid generator.

Examples of the above photo acid-generator include diazomethane compounds, diphenyliodonium salts, triphenylsulfonium salts, sulfonium salts, ammonium salts, phosphonium salts and sulfonamide compounds. The structures of those photo acid-generators can be represented by the formula (A):

R⁺X⁻ (A).

Wherein the formula (A), R⁺ is hydrogen or an organic ion modified by carbon atoms or other hetero atoms provided that the organic ion is selected from the group consisting of alkyl groups, aryl groups, alkenyl groups, acyl groups and alkoxy groups. For example, R⁺ is diphenyliodonium ion or triphenylsulfonium ion.

Further, X⁻ is preferably a counter ion represented by any of the following formulas:

SbY₆⁻,

AsY₆⁻,

R^{a}ₚPY₆₋ₚ⁻,

R^{a}_{q}BY_{4-q}⁻,

R^{a}_{q}GaY_{4-q}⁻,

R^{a}SO₃⁻,

(R^{a}SO₂)₃C⁻,

(R^{a}SO₂)₂N⁻,

R^{a}COO⁻, and

SCN⁻

in which
Y is a halogen atom,
R^{a} is an alkyl group of 1 to 20 carbon atoms or an aryl group of 6 to 20 carbon atoms provided that each group is substituted with a substituent group selected from the group consisting of fluorine, nitro group and cyano group,
R^{b} is hydrogen or an alkyl group of 1 to 8 carbon atoms,
P is a number of 0 to 6, and
q is a number of 0 to 4.

Concrete examples of the counter ion include: BF₄⁻, (C₆F₅)₄B⁻, ((CF₃)₂C₆H₃)₄B⁻, PF₆⁻, (CF₃CF₂)₃ PF₃⁻, SbF₆⁻, (C₆F₅)₄Ga⁻, ((CF₃)₂C₆H₃)₄Ga⁻, SCN⁻, (CF₃SO₂)₃C⁻, (CF₃SO₂)₂N⁻, formate ion, acetate ion, trifluoromethanesulfonate ion, nonafluorobutanesulfonate ion, methanesulfonate ion, butanesulfonate ion, benzenesulfonate ion, p-toluenesulfonate ion, and sulfonate ion.

Among the photo acid-generators usable in the present invention, those generating sulfonic acids or boric acids are particularly preferred. Examples thereof include tricumyliodonium teterakis (pentafluorophenyl) borate (PHOTOINITIATOR2074 [trademark], manufactured by Rhodorsil), diphenyliodonium tetra(perfluorophenyl) borate, and a compound having sulfonium ion and pentafluoroborate ion as the cation and anion moieties, respectively. Further, examples of the photo acid-generators also include triphenylsulfonium trifluoromethanesulfonate, triphenylsulfonium camphorsulfonate, triphenylsulfonium tetra(perfluorophenyl) borate, 4-acetoxyphenyldimethylsulfonium hexafluoroarsenate, 1-(4-n-butoxynaphthalene-1-yl)tetrahydrothiophenium trifluoromethanesulfonate, 1-(4,7-dibutoxy-1-naphthalenyl)tetrahydrothiophenium trifluoromethanesulfonate, diphenyliodonium trifluoromethanesulfonate, and diphenyliodonium hexafluoro-arsenate. Furthermore, it is still also possible to adopt photo acid-generators represented by the following formulas:

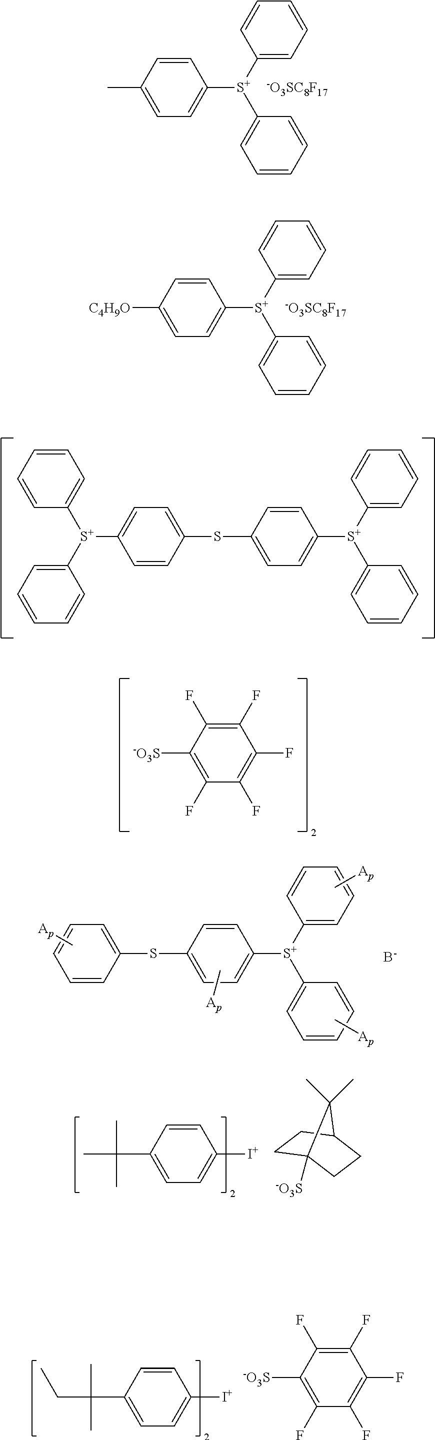

in which
each A is independently a substituent group selected from the group consisting of an alkyl group of 1 to 20 carbon atoms, an alkoxy group of 1 to 20 carbon atoms, an aryl group of 6 to 20 carbon atoms, an alkylcarbonyl group of 1 to 20 carbon atoms, an arylcarbonyl group of 6 to 20 carbon atoms, hydroxyl group, and amino group;
each p is independently an integer of 0 to 5; and
B⁻ is a fluorinated alkylsulfonate group, a fluorinated arylsulfonate group, a fluorinated alkylborate group, an alkylsulfonate group or an arylsulfonate group.

It is also possible to use photo acid-generators in which the cations and anions in the above formulas are exchanged each other or combined with various other cations and anions described above. For example, any one of the sulfonium ions represented by the above formulas can be combined with tetra(perfluorophenyl) borate ion, and also any one of the iodonium ions represented by the above formulas can be combined with tetra(perfluorophenyl) borate ion. Those can be still also employed as the photo acid-generators.

In the present invention, the photo radical generator is more preferable in terms of process shortening and cost since the reaction is initiated immediately after the radiation irradiation and the reheating process performed after the radiation irradiation and before the developing process can be omitted.

The photo radical generator can improve the resolution by strengthening the pattern shape or increasing the contrast of development. The photo radical generator used in the present invention is a photo radical generator that emits a radical when irradiated with radiation. Here, examples of the radiation include visible light, ultraviolet light, infrared light, X-ray, electron beam, α-ray, and γ-ray.

The addition amount of the photo radical generator is preferably 0.001 to 50 mass %, more preferably 0.01 to 30 mass %, based on the total mass of the alkali-soluble polymer, though the optimal amount thereof depends on the type and amount of active substance generated by decomposition of the photo radical generator, the required photosensitivity, and the required dissolution contrast between the exposed area and unexposed area. If the addition amount is less than 0.001 mass %, the dissolution contrast between the exposed area and unexposed portion is too low, and the addition effect is not sometimes exhibited. On the other hand, when the addition amount of the photo radical generator is more than 50 mass %, colorless transparency of the coated film sometimes decreases, because it sometimes occurs that cracks are generated in the coated film to be formed and coloring due to decomposition of the photo radical generator becomes remarkable. Further, when the addition amount becomes large, thermal decomposition of the photo radical generator causes deterioration of the electrical insulation of the cured product and release of gas, which sometimes become a problem in subsequent processes. Further, the resistance of the coated film to a photoresist stripper containing monoethanolamine or the like as a main component sometimes deteriorates.

Examples of the photo radical generator include azo-based, peroxide-based, acylphosphine oxide-based, alkylphenone-based, oxime ester-based, and titanocene-based initiators. Among them, alkylphenone-based, acylphosphine oxide-based and oxime ester-based initiators are preferred, and 2,2-dimethoxy-1,2-diphenylethan-1-one, 1-hydroxy-cyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)-benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)-phenyl]-1-butanone, 2,4,6-trimethylbenzoyldiphenyl phosphine oxide, bis(2,4,6-trimethylbenzoyl)-phenyl-phosphine oxide, 1,2-octanedione, 1-[4-(phenylthio)-2-(O-benzoyloxime)], ethanone, 1-[9-ethyl-6-(2-methylbenzoyl)-9H-carbazol-3-yl]-1-(O-acetyloxime), Bis(2,4-cyclopentadienyl)bis [2,6-difluoro-3-(1H-pyrrole-1-yl)phenyl]titanium (IV) and the like are included.

### Other Additives

The composition according to the present invention can optionally comprise other additives. As such additives, a developer dissolution accelerator, a scum remover, an adhesion enhancer, a polymerization inhibitor, an antifoaming agent, a surfactant, a photosensitizing enhancing agent, a crosslinking agent, a curing agent can be added.

Thus, according to the present invention, preferably the composition further comprises at least one additive selected from one or more members of the group consisting of a developer dissolution accelerator, a scum remover, an adhesion enhancer, a polymerization inhibitor, an antifoaming agent, a surfactant, a photosensitizing enhancing agent, a crosslinking agent, and/or a curing agent.

The developer dissolution accelerator or scum remover has a function of adjusting the solubility of the formed coated film in the developer and preventing scum from remaining on the substrate after development. As such an additive, crown ether can be used. The crown ether having the simplest structure is represented by the general formula (—CH₂—CH₂—O—)ₙ. Preferred in the present invention are those in which n is 4 to 7. When x is set to be the total number of atoms constituting the ring and y is set to be the number of oxygen atoms contained therein, the crown ether is sometimes called x-crown-y-ethers. In the present invention, preferred is selected from the group consisting of crown ethers, wherein x=12, 15, 18 or 21, and y=x/3, and their benzo condensates and cyclohexyl condensates. Specific examples of more preferred crown ethers include 21-crown-7-ether, 18-crown-6-ether, 15-crown-5-ether, 12-crown-4-ether, dibenzo-21-crown-7-ether, dibenzo-18-crown-6-ether, dibenzo-15-crown-5-ether, dibenzo-12-crown-4-ether, dicyclohexyl-21-crown-7-ether, dicyclohexyl-18-crown-6-ether, dicyclo-hexyl-15-crown-5-ether, and dicyclohexyl-12-crown-4-ether. In the present invention, among them, most preferred is selected from 18-crown-6-ether and 15-crown-5-ether. The content thereof is preferably 0.05 to 15 mass %, more preferably 0.1 to 10 mass %, based on the total mass of the alkali-soluble polymer.

The adhesion enhancer has an effect of preventing a pattern from peeling off due to stress applied after baking when a cured film is formed using the composition according to the present invention. As the adhesion enhancer, imidazoles, silane coupling agents, and the like are preferred. Among imidazoles, 2-hydroxybenzimidazole, 2-hydroxyethylbenzimidazole, benzimidazole, 2-hydroxyimidazole, imidazole, 2-mercaptoimidazole and 2-aminoimidazole are preferable, and 2-hydroxybenzimidazole, benzimidazole, 2-hydroxyimidazole and imidazole are particularly preferably used.

As the silane coupling agent, known ones are suitably used, and examples thereof include epoxy silane coupling agents, amino silane coupling agents, mercapto silane coupling agents, and the like. Specifically, 3-glycidoxypropyltrimethoxysilane, 3-glycidoxypropyl-triethoxysilane, N-2-(aminoethyl)-3-aminopropyltri-methoxysilane, N-2-(aminoethyl)-3-aminopropyltri-ethoxysilane, 3-aminopropyltrimethoxysilane, 3-amino-propyltriethoxysilane, 3-ureidopropyltriethoxysilane, 3-chloropropyltriethoxysilane, 3-mercaptopropyltri-methoxysilane, 3-isocyanatopropyltriethoxysilane, and the like are preferred. These can be used alone or in combination of two or more, and the addition amount thereof is preferably 0.05 to 15 mass % based on the total mass of the alkali-soluble polymer.

Further, as the silane coupling agent, a silane compound and siloxane compound having an acid group, or the like can be used. Examples of the acid group include a carboxyl group, an acid anhydride group, a phenolic hydroxyl group, and the like. When it contains a monobasic acid group such as a carboxyl group or a phenolic hydroxyl group, it is preferred that a single silicon-containing compound has a plurality of acid groups.

Exemplified embodiments of such a silane coupling agent include a compound represented by the formula (C):

XₙSi(OR^{C3})₄₋ₙ (C)

or polymer obtained using it as a repeating unit. At this time, a plurality of repeating units having different X or R^{C3} can be used in combination.

In the formula, R^{C3} includes a hydrocarbon group, for example, an alkyl group such as a methyl group, an ethyl group, an n-propyl group, an isopropyl group, and an n-butyl group. In the general formula (C), a plurality of R^{C3} are included, and each R^{C3} can be identical or different.

As X, those having an acid group such as phosphonium, borate, carboxyl, phenol, peroxide, nitro, cyano, sulfo, and alcohol group are included, and those in which these acid groups are protected by acetyl, aryl, amyl, benzyl, methoxymethyl, mesyl, tolyl, trimethoxysilyl, triethoxysilyl, triisopropylsilyl or trityl group, and an acid anhydride group are included.

Among them, a compound having a methyl group as R^{C3} and a carboxylic acid anhydride group as X, such as an acid anhydride group-containing silicone, is preferable. More specifically, a compound represented by the following formula (X-12-967C (trade name, Shin-Etsu Chemical Co., Ltd.)) or polymer containing a structure corresponding thereto in its terminal or side chain of a silicon-containing polymer such as silicone is preferred.

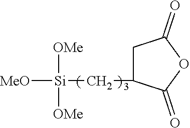 [SMILES: CO[Si](CC1CC(=O)OC1=O)(OC)OC]

Further, a compound in which thiol, phosphonium, borate, carboxyl, phenol, peroxide, nitro, cyano, and an acid group such as sulfo group is provided at the terminal of dimethyl silicone is also preferable. As such a compound, compounds represented by the following formulae (X-22-2290AS and X-22-1821 (trade name in every case, Shin-Etsu Chemical Co., Ltd.)) are included.

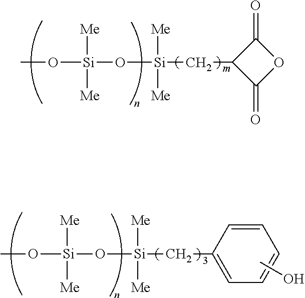

When the silane coupling agent has a silicone structure, if the molecular weight is too large, the compatibility with polysiloxane contained in the composition becomes poor, so that there is a possibility that there is an adverse effect such that the solubility in the developer does not improve, the reactive group remains in the film, and the chemical resistance that can withstand the subsequent process cannot be maintained. For this reason, the mass average molecular weight of the silane coupling agent is preferably 5,000 or less, and more preferably 4,000 or less. The content of the silane coupling agent is preferably 0.01 to 15 mass % based on the total mass of the alkali-soluble polymer.

As the polymerization inhibitor, an ultraviolet absorber as well as nitrone, nitroxide radical, hydroquinone, catechol, phenothiazine, phenoxazine, hindered amine and derivatives thereof can be added. Among them, methylhydroquinone, catechol, 4-t-butylcatechol, 3-methoxycatechol, phenothiazine, chlorpromazine, phenoxazine, TINUVIN 144, 292 and 5100 (BASF) as the hindered amine, and TINUVIN 326, 328, 384-2, 400 and 477 (BASF) as the ultraviolet absorber are preferred. These can be used alone or in combination of two or more, and the content thereof is preferably 0.01 to 20 mass % based on the total mass of the alkali-soluble polymer.

As the antifoaming agent, alcohols (C₁₋₁₈), higher fatty acids such as oleic acid and stearic acid, higher fatty acid esters such as glycerin monolaurate, polyethers such as polyethylene glycols (PEG) (Mn: 200 to 10,000) and polypropylene glycols (PPG) (Mn: 200 to 10,000), silicone compounds such as dimethyl silicone oil, alkyl-modified silicone oil and fluorosilicone oil, and organosiloxane-based surfactants described in detail below are included. These can be used alone or in combination of a plurality of these, and the content thereof is preferably 0.1 to 3 mass % based on the total mass of the alkali-soluble polymer.

### Photosensitizing Enhancing Agent

A photosensitizing enhancing agent can be optionally added to the bank composition according to the present invention. The photosensitizing enhancing agent preferably used in the composition according to the present invention includes coumarin, ketocoumarin and their derivatives, thiopyrylium salts, acetophenones, and the like, and specifically, p-bis(o-methylstyryl)benzene, 7-dimethylamino-4-methylquinolone-2,7-amino-4-methylcoumarin, 4,6-di-methyl-7-ethylaminocoumarin, 2-(p-dimethylamino-styryl)-pyridylmethyl-iodide, 7-diethylaminocoumarin, 7-diethylamino-4-methyl-coumarin, 2,3,5,6-1H,4H-tetrahydro-8-methyl-quinolizino-<9,9a, 1-gh>coumarin, 7-diethylamino-4-trifluoromethylcoumarin, 7-dimethyl-amino-4-trifluoro-methylcoumarin, 7-amino-4-trifluoro-methylcoumarin, 2,3,5,6-1H,4H-tetrahydroquinolizino-<9,9a, 1-gh>coumarin, 7-ethylamino-6-methyl-4-trifluoromethylcoumarin, 7-ethylamino-4-trifluoro-methylcoumarin, 2,3,5,6-1H,4H-tetrahydro-9-carbo-ethoxyquinolizino-<9,9a,1-gh>coumarin, 3-(2′-N-methylbenzimidazolyl)-7-N,N-diethylaminocoumarin, N-methyl-4-trifluoro-methylpiperidino-<3,2-g>coumarin, 2-(p-dimethylaminostyryl)-benzothiazolylethyl iodide, 3-(2′-benzimidazolyl)-7-N,N-diethylaminocoumarin, 3-(2′-benzothiazolyl)-7-N,N-diethylaminocoumarin, and sensitizing dyes such as pyrylium salts and thiopyrylium salts represented by the following chemical formula. By the addition of the sensitizing dye, patterning using an inexpensive light source such as a high-pressure mercury lamp (360 to 430 nm) becomes possible. The content thereof is preferably 0.05 to 15 mass %, more preferably 0.1 to 10 mass %, based on the total mass of the alkali-soluble polymer.

| 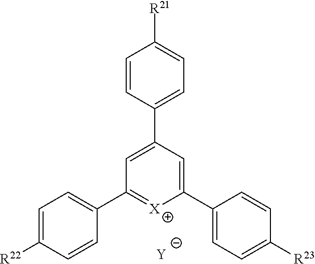 | | | | |
|---|---|---|---|---|
| X | R²¹ | R²² | R²³ | Y |
| S | OC₄H₉ | H | H | BF₄ |
| S | OC₄H₉ | OCH₃ | OCH₃ | BF₄ |
| S | H | OCH₃ | OCH₃ | BF₄ |
| S | N(CH₃)₂ | H | H | ClO₂ |
| O | OC₄H₉ | H | H | SbF₅ |

Further, as the photosensitizing enhancing agent, an anthracene skeleton-containing compound can be also used. Specifically, a compound represented by the following formula is included.

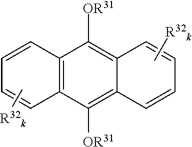

wherein, R³¹ each independently represents a substituent selected from the group consisting of an alkyl group, an aralkyl group, an allyl group, a hydroxyalkyl group, an alkoxyalkyl group, a glycidyl group, and a halogenated alkyl group,
R³² each independently represents a substituent selected from the group consisting of a hydrogen atom, an alkyl group, an alkoxy group, a halogen atom, a nitro group, a sulfonic acid group, a hydroxyl group, an amino group, and a carboalkoxy group, and k is each independently selected from 0 and an integer of 1 to 4.

When such a photosensitizing enhancing agent having an anthracene skeleton is used, its content is preferably 0.01 to 5 mass % based on the total mass of the alkali-soluble polymer.

In another aspect, the present invention further relates to a method for fabricating a cured layer comprising at least the following steps;
(Xi) providing the composition of the present invention onto a layer or onto a substrate to form a coated layer; and
(Xii) baking a coated layer to obtain a cured layer.

Preferably the method further comprises one or more of the following steps after step (Xi) and before the step (Xii):
(Xiii) Applying a pre-baking (heat treatment) of the coating layer in order to dry the coated layer and reduce the residual amount of the solvent in the coated layer. Preferably said pre-baking process is carried out at a temperature of generally 50 to 150° C., preferably 90 to 120° C., in the case of a hot plate, for 10 to 300 seconds, preferably 30 to 120 seconds and in the case of a clean oven, for 1 to 30 minutes;
(Xiv) irradiating the coated layer with light (applying light irradiation), preferably with light having peak maximum wavelength in the range from 360 to 430 nm, preferably a patterning mask is used when light irradiation is carried out;
(Xv) applying post exposure baking process; and/or
(Xvi) applying developing process to form a patterned cured layer.

### Method for Fabricating a Cured Layer (Preferably Bank Fabrication Process)

### Step (Xi): Application Process

First, the above-described composition is applied onto a substrate. Formation of the coating film of the composition in the present invention can be carried out by any method conventionally known as a method for applying a photosensitive composition. Specifically, it can be freely selected from dip coating, roll coating, bar coating, brush coating, spray coating, doctor coating, flow coating, spin coating, slit coating, and the like. Further, as the substrate on which the composition is applied, a suitable substrate such as a silicon substrate, a glass substrate, a resin film, and the like can be used. Various semiconductor devices and the like can be formed on these substrates as needed. When the substrate is a film, gravure coating can also be utilized. If desired, a drying process can be additionally provided after applying the film. Further, if necessary, the applying process can be repeated once or twice or more to make the film thickness of the coating film to be formed as desired.

### Step (Xiii): Pre-Baking Process

After forming the coating film of the composition by applying the composition, it is preferable to carry out pre-baking (heat treatment) of the coating film in order to dry the coating film and reduce the residual amount of the solvent in the coating film. The pre-baking process can be carried out at a temperature of generally 50 to 150° C., preferably 80 to 120° C., in the case of a hot plate, for 10 to 300 seconds, preferably 30 to 120 seconds and in the case of a clean oven, for 1 to 30 minutes.

### Step (Xiv): Exposure Process

After forming a coating film, the coating film surface is then irradiated with light. As the light source to be used for the light irradiation, any one conventionally used for a pattern forming method can be used. As such a light source, a high-pressure mercury lamp, a low-pressure mercury lamp, a lamp such as metal halide and xenon, a laser diode, an LED and the like can be included. As the irradiation light, ultraviolet ray such as g-line, h-line and i-line is usually used. Except ultrafine processing for semiconductors or the like, it is general to use light of 360 to 430 nm (high-pressure mercury lamp) for patterning of several μm to several dozens of μm. According to the present invention, the energy of the irradiation light and the irradiation time can be significantly reduced by using the composition of the present invention. It is preferably in the range from 5 to 150 mJ/cm², more preferably 8 to 100 mJ/cm², even more preferably from 10 to 80 mJ/cm² for the coated composition having 10 μm layer thickness, although it depends on the light source and the film thickness of the coating film. To obtain a sufficient resolution, irradiation light energy 5 mJ/cm² or more is suitable. And to avoid an excess exposure, occurrence of halation, and/or damage to a base layer, and/or improving fabrication process time, 150 mJ/cm² or less is highly desirable.

In order to irradiate light in a pattern shape, a general photomask can be used. Such a photomask can be freely selected from well-known ones. The environment at the time of irradiation is not particularly limited and can generally be set as an ambient atmosphere (in the air) or nitrogen atmosphere. Further, in the case of forming a film on the entire surface of the substrate, light irradiation can be performed over the entire surface of the substrate. In the present invention, the pattern film also includes such a case where a film is formed on the entire surface of the substrate.

### Step (Xv): Post Exposure Baking Process

After the exposure, to promote the reaction between the polymer in the film by the polymerization initiator, post exposure baking can be performed as necessary. But according to the present invneiton, it is not mandatory and can be skipped. Especially, by using the composition of the present invnetion, this post exposure baking process can be skipped. Different from the heating process (6) to be described later, this heating treatment is performed not to completely cure the coating film but to leave only a desired pattern on the substrate after development and to make other areas capable of being removed by development. Therefore, it is not essential in the present invention.

When the post exposure baking is performed, a hot plate, an oven, a furnace, and the like can be used. The heating temperature should not be excessively high because it is not desirable for the acid, base or radical in the exposed area, which is generated by light irradiation, to diffuse to the unexposed area. From such a viewpoint, the range of the heating temperature after exposure is preferably 50 to 150° C., and more preferably 80 to 120° C. Stepwise heating can be applied as needed to control the curing rate of the composition. Further, the atmosphere during the heating is not particularly limited and can be selected from in an inert gas such as nitrogen, under a vacuum, under a reduced pressure, in an oxygen gas, and the like, for the purpose of controlling the curing rate of the composition. Further, the heating time is preferably above a certain level in order to maintain higher the uniformity of temperature history in the wafer surface and is preferably not excessively long in order to suppress diffusion of the generated acid, base or radical. From such a viewpoint, the heating time is preferably 20 seconds to 500 seconds, and more preferably 40 seconds to 300 seconds.

### Step (Xvi): Developing Process

After post-exposure heating is optionally performed after exposure, the coating film is developed. As the developer to be used at the time of development, any developer conventionally used for developing a photosensitive composition can be used. Preferable examples of the developer include an alkali developer which is an aqueous solution of an alkaline compound such as tetraalkylammonium hydroxide, choline, alkali metal hydroxide, alkali metal metasilicate (hydrate), alkali metal phosphate (hydrate), a sodium carbonate aqueous solution, ammonia, alkylamine, alkanolamine and heterocyclic amine, and a particularly preferable alkali developer is a tetramethylammonium hydroxide aqueous solution, a potassium hydroxide aqueous solution, a sodium hydroxide aqueous solution, or a sodium carbonate aqueous solution. In this alkali developer, a water-soluble organic solvent such as methanol and ethanol, or a surfactant can be further contained, if necessary. In the present invention, the development can be performed using a developer having a lower concentration than a 2.38 mass % TMAH developer that is usually used as a developer. Examples of such a developer include a 0.05 to 1.5 mass % TMAH aqueous solution, a 0.1 to 2.5 mass % sodium carbonate aqueous solution, and a 0.01 to 1.5 mass % potassium hydroxide aqueous solution. The developing time is usually 10 to 300 seconds, preferably 30 to 180 seconds, more preferably 60-120 seconds. By using the composition of the present invention, such a short developing time can be realized. The developing method can also be freely selected from conventionally known methods. Specifically, methods such as dipping in a developer (dip), paddle, shower, slit, cap coat, spray, and the like can be included. After the development with a developer, by which a pattern can be obtained, it is preferable that rinsing with water is carried out.

### Step (Xii): Heating Process

After development, the obtained pattern film is cured by heating. As the heating apparatus used for the heating process, the same one as used for the above-described post-exposure heating can be used. The heating temperature in this heating process is not particularly limited as long as it is a temperature at which curing of the coating film can be performed, and it can be freely determined.

The composition according to the invention is capable of being cured at relatively low temperature. Specifically, it is preferable to cure by heating at 180° C. or lower, and in order to maintain a high remaining film ratio after curing, the curing temperature is more preferably 150° C. or lower, and particularly preferably 120° C. or lower.

On the other hand, in order to accelerate the curing reaction and obtain a sufficiently cured film, the curing temperature is preferably 50° C. or higher, more preferably 80° C. or higher. According to the present invention, low curing temperature such as around 100° C. is more preferable. Further, the heating time is not particularly limited and is generally 10 minutes to 90 minutes, and preferably 20 minutes to 60 minutes. In addition, this heating time is a time from when the temperature of the pattern film reaches a desired heating temperature. Usually, it takes about several minutes to several hours for the pattern film to reach a desired temperature from the temperature before heating.

In another aspect, the present invention further relates to a layer obtained or obtainable from the method of the present invention.

In another aspect, the present invention further relates to a layer comprising at least, essentially consisting of or consisting of;
i) a polymer (A) derived or derivable from an alkaline-soluble polymer containing an ethylenic double bond;
preferably the solid acid value of the alkaline polymer is in the range from 30 to 160 mgKOH/g, more preferably from 50 to 150 mg KOH/g, even more preferably from 60 to 80 mg KOH/g,
preferably the weight-average molecular weight of said alkaline-soluble polymer is in the range from 1,000 to 100,000, more preferably it is from 1,200 to 30,000, even more preferably it is from 3000 to 8000,
preferably said alkaline-soluble polymer is selected from (meth)acrylate polymer, more preferably it is a methacrylate polymer, an acrylate polymer or a combination of thereof, even more preferably the polymer material is an acrylate polymer; and
   ii) a colorant.

Preferably said layer is a patterned layer.

Preferably said polymer (A) is derived or derivable from the alkaline-soluble polymer and another material selected from a thiol containing polyfunctional chemical compound, a fluorine containing surfactant having at least one crosslinking group or a combination of thereof.

Preferably said colorant is a 1^{st} colorant as already defined in the section of “Colorant” above. The layer may optionally contain another colorant such as 2^{nd} colorant, 3^{rd} colorant and/or a surfactant as already indicated.

In a preferable embodiment of the present invention, the Optical Density (OD) value of the layer at 10 μm layer thickness at light wavelength 460 nm is in the range from 1.0 to 4.0, preferably it is in the range from 1.5 to 2.5, more preferably from 1.8 to 2.2. The OD value of the layer at 10 μm layer thickness at light wavelength 540 nm is in the range from 1.0 to 4.0, preferably it is in the range from 1.5 to 2.5, more preferably from 1.8 to 2.2.

The OD value of the layer at 10 μm layer thickness at light wavelength 630 nm is in the range from 1.0 to 3.0, preferably it is in the range from 1.5 to 2.5, more preferably from 1.8 to 2.2.

In a preferable embodiment of the present invention, the average reflection value of the layer at 10 μm layer thickness in the light wavelength range from 450-650 nm is in the range from 20 to 70%, preferably from 30 to 60%, more preferably from 40 to 55%.

In another aspect, the present invention further relates to a light converting device comprising at least the layer of the present invention. Preferably said light converting device furhter comprises a substrate. Preferably siad light converting device is a color filter, a pixelerated color conversion device.

In another aspect, the present invention further relates to an optical device comprising at least the layer of the present invention or a light converting device of the present invention. Preferably said optical device is a display device, more preferably said display device is selected from the group consisiting of OLED, LCD, LED and μLED.

In another aspect, the present invention further relates to use of the composition of the present invention, or the layer of the present invention in a fabrication process of a light converting device.

In another aspect, the present invention further relates to use of the light converting device of the present invention in a fabrication process of an optical device.

In another aspect, the present invention further relates to a method of fabricating an optical device comprising at least;
providing the light converting device of the present invention into an optical device.

### Preferable Embodiments

1. A composition, preferably it is being of a photocurable composition, preferably said composition does not contain any polysiloxane,
comprising at least, essentially consisting of or consisting of;
   ii. an alkaline-soluble polymer containing an ethylenic double bond;
preferably the weight-average molecular weight of said alkaline-soluble polymer is in the range from 1,000 to 100,000, more preferably it is from 1,200 to 30,000, even more preferably it is from 3000 to 8000,
preferably said alkaline-soluble polymer is selected from (meth)acrylate polymer, more preferably it is a methacrylate polymer, an acrylate polymer or a combination of thereof, even more preferably the polymer material is an acrylate polymer; and
   iii. a colorant.

2. The composition of embodiment 1, he solid acid value of the alkaline polymer is in the range from 30 to 160 mgKOH/g, more preferably from 50 to 150 mg KOH/g, even more preferably from 60 to 80 mg KOH/g.

3. The composition of embodiment 1 or 2, further comprises a thiol containing polyfunctional chemical compound. Preferably said thiol containing polyfunctional chemical compound contains a pentaerythritol structure. More preferably said thiol containing polyfunctional chemical compound is represented by following chemical formula (I^{x})

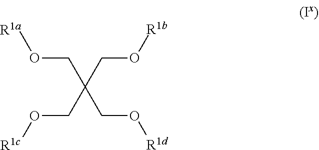

wherein
R^{1a}, R^{1b}, R^{1c} and R^{1d} are, independently of each other, selected from a hydrogen atom, alkyl chain having 1 to 10 carbon atoms, cyclo group having 3 to 10 carbon atoms cyclo-alkyl group having 4 to 10 carbon atoms, aryl group having 3 to 10 carbon atoms or an alkoxy group having 1 to 10 carbon atoms, where at least one H atom is replaced with SH group, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂, wherein at least one of R^{1a}, R^{1b}, R^{1c} and Rid is not a hydrogen atom, preferably at least two of R^{1a}, R^{1b}, R^{1c} and Rid are not a hydrogen atom, more preferably at least R^{1a}, R^{1b}, R^{1c} are not a hydrogen atom.

Preferably the total amount of the thiol containing polyfunctional chemical compound based on the total amount of the alkaline-soluble polymer is in the range from 10 wt % to 200 wt. %, preferably in the range from 30 wt % to 150 wt %, more preferably from 50 wt % to 100 wt %.

4. The composition of any one of preceding embodiments, further comprises a chemical compound containing at least two (meth)acryloyloxy groups.

Preferably said at least two (meth)acryloyloxy groups are two or more acryloyloxy groups, methacryloyloxy groups or a combinaiton of these, preferably the total amount of the chemical compound containing said at least two (meth)acryloyloxy groups based on the total amount of the alkaline-soluble polymer is in the range from 5 wt. % to 1,000 wt. %, more preferably from 10 wt. % to 500 wt. %, even more preferably it is from 15 wt. % to 300 wt. %, preferably said chemical compound is a monomer having the molecular weight 2000 or less, more preferably in the range from 2000 to 50, even more preferably from 1000 to 100 preferably it is a poly acrylate monomer having at least three (meth)acryloyloxy groups, more preferably it is a poly acrylate monomer selected from one or more member of the group consisting of a poly acrylate monomer having three (meth)acryloyloxy groups, a poly acrylate monomer having four (meth)acryloyloxy groups, a poly acrylate monomer having five (meth)acryloyloxy groups, a poly acrylate monomer having six (meth)acryloyloxy groups, even more preferably it is a poly acrylate monomer having five (meth)acryloyloxy groups, a poly acrylate monomer having six (meth)acryloyloxy groups or a mixture of thereof,
preferably said poly acrylate monomer having three (meth)acryloyloxy groups is selected from one or more member of the group consisting of trimethylolpropane triacrylate, trimethylolpropaneethoxy triacrylate, trimethylolpropanepropoxy triacrylate, glycerinpropoxy triacrylate, pentaerythritol triacrylates;
preferably said poly acrylate monomer having four (meth)acryloyloxy groups is selected from one or more member of the group consisting of pentaerythritol tetraacrylates, ditrimethylolpropane tetraacrylate, pentaerythritolehoxy tetraacrylates;
preferably said poly acrylate monomer having five (meth)acryloyloxy groups is dipentaerythritol hexaacrylates, preferably said poly acrylate monomer having six (meth)acryloyloxy groups is dipentaerythritol pentaacrylate, the most preferably said chemical compound is dipentaerythritol hexaacrylates, dipentaerythritol pentaacrylate or a mixture of thereof.

5. The composition of any one of preceding embodiments, further comprises a surfactant.

Preferably said surfactant is a halogen containing surfactant, more preferably it is a halogen containing surfactant, preferably said surfactant has at least one crosslinking group, preferably said halogen is selected from fluorine, chlorine, bromine and iodine, more preferably said halogen is fluorine, more preferably said surfactant is a halogen containing surfactant having at least one crosslinking group, even more preferably it is a fluorine containing surfactant having at least one crosslinking group, furthermore preferably said surfactant is a fluorine containing surfactant having at least one crosslinking group containing a perfluoroalkyl group or perfluoro alkylene group;
preferably the total amount of the surfactant is in the range from 0.0001 to 3 wt. %, more preferably from 0.001 to 1 wt. %, even more preferably from 0.01 to 0.6 wt. %, furthermore preferably from 0.1 to 0.3 wt % based on the total solid contents of the composition.

6. The composition of any one of preceding embodiments, further comprises a solvent, prefrably said solvent is selected from one or more of the members of the group consisting of ethylene glycol monoalkyl ethers, preferably selected from ethylene glycol monomethyl ether, ethylene glycol monoethyl ether, ethylene glycol monopropyl ether and ethylene glycol monobutyl ether; diethylene glycol dialkyl ethers, preferably selected from diethylene glycol dimethyl ether, diethylene glycol diethyl ether, diethylene glycol dipropyl ether and diethylene glycol dibutyl ether; ethylene glycol alkyl ether acetates, preferably selected from methyl cellosolve acetate and ethyl cellosolve acetate; propylene glycol monoalkyl ethers, preferably selected from propylene glycol monomethyl ether and propylene glycol monoethyl ether; propylene glycol alkyl ether acetates, preferalbly it is selected from PGMEA, propylene glycol monoethyl ether acetate and propylene glycol monopropyl ether acetate; aromatic hydrocarbons, preferably selected from benzene, toluene and xylene; ketones, preferably selected from methyl ethyl ketone, acetone, methyl amyl ketone, methyl isobutyl ketone and cyclohexanone; alcohols, preferably selected from ethanol, propanol, butanol, hexanol, cyclohexanol, ethylene glycol and glycerin; esters, preferably selected from ethyl lactate, ethyl 3-ethoxypropionate and methyl 3-methoxypropionate; and cyclic esters, preferably it is γ-butyrolactone, more preferably said solvent is a combination of propylene glycol alkyl ether acetates or esters, and cyclic esters that is preferably γ-butyrolactone, preferably the total amount of said solvent based on the total amount of the composition is in the range from 1 wt. % to 99 wt. %, preferably from 5 wt. % to 90 wt. %, even more preferably from 10 wt. % to 80 wt. %, furthermore preferably from 20 wt. % to 70 wt. %.

7. The composition of any one of preceding embodiments, said colorant is a 1^{st} colorant selected from an organic colorant and/or an inorganic colorant, more preferably it is a black colorant selected from an organic black pigment and/or inorganic black pigment or a white colorant selected from an organic white pigment and/or inorganic white pigment,
preferably said black colorant has a light transmittance ratio represented by [light transmittance at the wavelength of 365 nm]/[average light transmittance in the wavelength range 450 nm to 650 nm] of 3.5 or more, more preferably the ratio is 5.0 or more, furthermore preferably the ratio is 10 or more, preferably said black colorant has a light transmittance ratio represented by [light transmittance at the wavelength of 365 nm]/[average light transmittance in the wavelength range 450 nm to 650 nm] of 100 or less, more preferably 30 or less, evenmore preferably it is in the range from 3.5 to 100, furter more preferably it is from 5.0 to 30, particulary preferably from 10 to 30, provided that the transmittance is obtained by the follwoing formula:

The transmittance=the transmittance of Film 1*1/(the transmittance of Film 2)*100

### Fabrication and Measurment of the Transmittance of Film 1:

Film 1 is Obtained by the Following Steps:
applying a compoisiton in which 35 wt. % of a black colorant is dispersed based on the total amount of the total solid components of the composition (components without solvent) to a glass substrate, to form a film having film thickness of 10 μm, and curing at 85° C. to obtain the Film 1.

Measurement of Film 1: the obtained film is measured using Spectrophotometric colorimeter (CM-5, Konica Minolta).

Fabrication and measurment of the transmittance of Film 2:

Film 2 is obtained by the following steps:
applying a compoisiton in which no black colorant is dispersed in the composition to a glass substrate to obtain a film having film thickness of 10 μm and curing at 85° C. to obtain the Film 2.

Measurement of Film 2: the obtained film is measured using Spectrophotometric colorimeter (CM-5, Konica Minolta).

Preferably said colorant is an inorganic black pigment, more preferably said colorant is an inorganic black pigment selected from zirconium nitride and/or a titanium oxide, which may be coated by a polymer and/or inorganic layer, and/or
preferably said colorant is an organic black pigment, preferably it is a mixture of two or more organic color pigments, more preferably it is a mixture of red, green blue organic color pigments configured to show black color by mixing, further more preferably said organic black pigment is a mixture selected from the group consisting of an azo type, a cyanine type, a phthalocyanine type, a quinacridone type, a coumarin type, a benzimidazolone type, an isoindolinone type, a dioxazine type, an indanthrene type and a perylene type organic pigments.

8. The composition of any one of preceding embodiments, further comprises another colorant different from the colorant of embodiment 1.

Preferably said another colorant is a 2^{nd} colorant selected from an organic colorant and/or an inorganic colorant, more preferably it is a black colorant selected from an organic black pigment and/or inorganic black pigment or a white colorant selected from an organic white pigment and/or inorganic white pigment, even more preferably it is a white colorant selected from an organic white pigment and/or inorganic white pigment, furthermore preferably it is an inorganic white colorant.

9. The composition of any one of preceding embodiments, further comprises 3^{rd} colorant different from the colorant of embodiment 1 and the colorant of embodiment 7.

Preferably said 3^{rd} colorant is an inorganic black pigment, more preferably said colorant is an inorganic black pigment selected from zirconium nitride and/or a titanium oxide, which may be coated by a polymer and/or inorganic layer.

10. The composition of any one of preceding embodiments, the amount of the colorant (the 1^{st} colorant) is in the range from 0.1 to 50 wt % based on the total weight of the alkaline-soluble polymer of the composition, preferably it is from 1 to 30 wt %, more preferably from 1.5 to 20 wt %, even more preferably from 2.0 to 15 wt %.

11. The composition of any one of preceding embodiments, the amount of the another colorant (the 2^{nd} colorant) is in the range from 1 wt % to 400 wt %, preferably from 5 wt % to 300 wt %, more preferably from 10 wt % to 200 wt % based on the total weight of the alkaline-soluble polymer of the composition.

12. The composition of any one of preceding embodiments, the ratio of the colorant (the 1^{st} colorant) to the another colorant (the 2^{nd} colorant) is in the range from 0.0001 to 50.

13. The composition of any one of preceding embodiments, further comprises a polymerization initiator. Preferably said polymerization initiator is a photo-radical initiator.

14. The composition of any one of preceding embodiments, further comprises at least one additive selected from one or more members of the group consisting of a developer dissolution accelerator, a scum remover, an adhesion enhancer, a polymerization inhibitor, an antifoaming agent, a surfactant, a photosensitizing enhancing agent, a crosslinking agent, a curing agent. Preferably the amount of the amount of the another colorant (the 3^{rd} colorant) is in the range from based on the total weight of the alkaline-soluble polymer of the composition.

15. A method for fabricating a cured layer comprising at least the following steps;
(Xi) providing the composition of any one of embodiments 1 to 14 onto a layer or onto a substrate to form a coated layer; and
(Xii) baking a coated layer to obtain a cured layer.

Preferably the method further comprises one or more of the following steps after step (Xi) and before the step (Xii):
(Xiii) Applying a pre-baking (heat treatment) of the coating layer in order to dry the coated layer and reduce the residual amount of the solvent in the coated layer.

Preferably the pre-baking process is carried out at a temperature of generally 50 to 150° C., more preferably 80 to 120° C., in the case of a hot plate, for 10 to 300 seconds, 30 to 120 seconds and in the case of a clean oven, for 1 to 30 minutes;
(Xiv) irradiating the coated layer with light (applying light irradiation), preferably with light having peak maximum wavelength in the range from 360 to 430 nm, preferably a patterning mask is used when light irradiation is carried out;
(Xv) applying post exposure baking process; and/or
(Xvi) applying developing process to form a patterned cured layer.

Preferably the post-baking process is carried out at a temperature in the range from 50 to 150° C., more preferably from 80 to 120° C., for 1 to 180 minutes in the case of a clean oven, preferably 10 to 90 minutes, more preferably from 20 to 60 minutes;

16. A layer obtained or obtainable from the method of embodiment 15.

17. A layer comprising at least;
iv. a polymer (A) derived or derivable from an alkaline-soluble polymer containing an ethylenic double bond;
   preferably the solid acid value of the alkaline polymer is in the range from 30 to 160 mgKOH/g, more preferably from 50 to 150 mg KOH/g, even more preferably from 60 to 80 mg KOH/g,
   preferably the weight-average molecular weight of said alkaline-soluble polymer is in the range from 1,000 to 100,000, more preferably it is from 1,200 to 30,000, even more preferably it is from 3000 to 8000, preferably said alkaline-soluble polymer is selected from (meth)acrylate polymer, more preferably it is a methacrylate polymer, an acrylate polymer or a combination of thereof, even more preferably the polymer material is an acrylate polymer; and
ii) a colorant, preferably said layer is a patterned layer.

Preferably said polymer (A) is derived or derivable from the alkaline-soluble polymer and another material selected from a thiol containing polyfunctional chemical compound, a fluorine containing surfactant having at least one crosslinking group or a combination of thereof.

Preferably said colorant is as defined in embodiment 7. Preferably said layer may furhter comprise another colorant(s) as defined in any one of the embodiments 8 to 12.

18. The layer of embodiment 16 or 17, wherein the Optical Dencity (OD) value of the layer at 10 μm layer thickness at light wavelength 460 nm is in the range from 1.0 to 4.0, preferably it is in the range from 1.5 to 2.5, more preferably from 1.8 to 2.2. The OD value of the layer at 10 μm layer thickness at light wavelength 540 nm is in the range from 1.0 to 4.0, preferably it is in the range from 1.5 to 2.5, more preferably from 1.8 to 2.2.

And/or the OD value of the layer at 10 μm layer thickness at light wavelength 630 nm is in the range from 1.0 to 3.0, preferably it is in the range from 1.5 to 2.5, more preferably from 1.8 to 2.2.

19. The layer of any one of embodiments 16 to 18, wherein the average reflection value of the layer at 10 μm layer thickness in the light wavelength range from 450-650 nm is in the range from 20 to 70%, preferably from 30 to 60%, more preferably from 40 to 55%.

20. A light converting device comprising at least the layer of any one of embodiments 16 to 19. Preferably said light converting device further comprises a substrate.

21. An optical device comprising at least the layer of any one of embodiments 16 to 19 or a light converting device of embodiment 20.

22. Use of the composition of any one of embodiments 1 to 14, or the layer of any one of embodiments 16 to 19 in a fabrication process of a light converting device.

23. Use of the light converting device of embodiment 19 in a fabrication process of an optical device.

24. Method of fabricating an optical device comprising at least;
providing the light converting device of embodiment 20 into an optical device.

### Technical Effects of the Invention

Present invention provides one or more of the following effects: enabling development with a low-concentration alkaline developer, preferably in a shorter development time and/or achieving both reactivity and storage stability of the composition, realizing high sensitivity of the composition lowering exposure energy and exposure time, improving structure of a patterned cured film (bank structure), especially improving bottom side structure of a patterned cured film, providing improved curability of the bottom side of the coated composition, realizing improved reflection and/or high optical density (OD) of the cured film, especially realizing improved reflection and/or high OD of the cured film having white and black pigments (grey colored bank).

The working examples below provide descriptions of the present invention, as well as an in-detail description of their fabrication. However, the present invention is not necessary to be limited to the working examples.

### Working Examples

### Working Example 1: Preparation of Bank Composition

The bank composition 1 is prepared with using the following materials.

TABLE 1

| Alkaline-soluble polymer | Acryl polymer A | 100 wt. parts |
|---|---|---|
| | Acryl polymer B | 100 wt. parts |
| Chemical compound | A-DPH (Shin-Nakamura) | 310 wt. parts |
| containing at least two | | |
| (meth)acryloyloxy groups | | |
| (Monomer) | | |
| Photo-radical Initiator A | NCI-831 (Adeka) | 4.0 wt. parts |
| Photo-radical Initiator B | Omirad784 (IGM resins) | 6.2 wt. parts |
| Thiol containing | KarentsMT PE-1 | 70 wt. parts |
| polyfunctional chemical | (Showa Denko) | |
| compound | | |
| Surfactant A | Fluorine containing | 0.18 wt. parts |
| | surfactant A (DIC) | |
| Colorant 1 | Black dye containing dye | 11.6 wt. parts |
| | A, B and C (Hayashibara) | in total |
| Colorant 2 (White) | TiO₂ particle dispersion | 50 wt. parts |
| | A (Toyocolor) | |
| Colorant 3 (Black) | Black pigment 1 | 20 wt. parts |
| | (Toyocolor) | |
| Total solid | | 543.7 wt.parts |
| contents (100%) | | |
| Solvent | PGMEA | |
| Total | | 100% |

Acryl polymer A: acrylic randam polymer made from carbon acid monomer and monomer containing at least one aromatic ring group (Shin-Nakamura Chemical Co.,Ltd.).

Acryl polymer B: 2-Propenoic acid, 2-methyl-, polymer with 2-hydroxyethyl 2-methyl-2-propenoate, 2-isocyanatoethyl 2-propenoate and methyl 2-methyl-2-propenoate (Natoco).

PGMEA solvent is added so that the composition contains 35 wt % of total solid contents and 65 wt % of solvent based on the total weight of the compositioin after addting the solvent.

### Working Examples 2-20: Preparation of Bank Compositions

The bank compositions 2-11 are prepared in the same manner as described in working example 1 above except for that the following materials as mentioned in table 2A,2B are used instead of the materials used in working example 1. Here PGMEA solvent (not mentioned in the table 2) is added so that the composition contains 35 wt % of total solid contents and 65 wt % of solvent based on the total weight of the compositioin after addting the solvent as same to working example 1.

TABLE 2A

| | | Working examples | | | | | | | | | |
|---|---|---|---|---|---|---|---|---|---|---|---|
| | | 1 | 2 | 3 | 4 | 5 | 6 | 7 | 8 | 9 | 10 |
| Chemical compound containing | A-DPH | 310 | 310 | 310 | 310 | 310 | 310 | 310 | 310 | 310 | 310 |
| at least two (meth)acryloyloxy | (Shin-Nakamura) | | | | | | | | | | |
| groups (Monomer) | | | | | | | | | | | |
| Alkaline soluble polymer | Acryl polymer A | 100 | 100 | 100 | 100 | 100 | 100 | 100 | 100 | 100 | 100 |
| Alkaline soluble polymer | Acryl polymer B | 100 | 100 | 100 | 100 | 100 | 100 | 100 | 100 | 100 | 100 |
| Colorant 2 | TiO2 particle dispersion | | | | | 132 | 132 | 100 | 60 | 20 | 20 |
| (White pigment) | (Tokushiki) | | | | | | | | | | |
| Colorant 2 | TiO2 particle dispersion A | 50 | 70 | 90 | 90 | | | | | | |
| (White pigment) | (Toyocolor) | | | | | | | | | | |
| Colorant 3 | Black pigment 1 | 20 | 20 | 16 | 10 | | | | | | |
| (Black pigment) | (Toyocolor) | | | | | | | | | | |
| Colorant 1 (Black dye | Dye A | 3.8 | 3.8 | 3.8 | 3.8 | 3.8 | 3.4 | 3.8 | 3.8 | 3.8 | 4 |
| containing dye A, B and C; | Dye B | 3.4 | 3.4 | 3.4 | 3.4 | 3.4 | 2 | 2.4 | 2.4 | 2.5 | 2.9 |
| Hayashibara ) | Dye C | 4.4 | 4.4 | 4.4 | 4.4 | 4.4 | 2.2 | 3.4 | 3.4 | 3.6 | 4.2 |
| Photo-radical Initiator A | NCI-831 | 4 | 4 | 4 | 4 | 4 | 4 | 4 | 4 | 4 | 4 |
| Photo-radical Initiator B | Omnirad 784 | 6.2 | 6.2 | 6.2 | 6.2 | 6.2 | 6.2 | 6.2 | 6.2 | 6.2 | 6.2 |
| Thiol containing polyfunctional | KarenzMT PE-1 | 70 | 70 | 70 | 70 | 70 | 70 | 70 | 70 | 70 | 70 |
| chemical compound | | | | | | | | | | | |
| Fluorine containing surfactant | Fluorine containing | 0.18 | 0.18 | 0.18 | 0.18 | 0.18 | 0.18 | 0.18 | 0.18 | 0.18 | 0.18 |
| having crosslinking group | surfactant A (DIC) | | | | | | | | | | |

TABLE 2B

| | | Working examples | | | | | | | | | |
|---|---|---|---|---|---|---|---|---|---|---|---|
| | | 11 | 12 | 13 | 14 | 15 | 15 | 17 | 18 | 19 | 20 |
| Chemical compound containing | A-DPR | 310 | 310 | 310 | 310 | 310 | 310 | 310 | 310 | 310 | 310 |
| at least two (meth)acryloyloxy | (Shin-Nakamura) | | | | | | | | | | |
| groups (Monomer) | | | | | | | | | | | |
| Alkaline soluble polymer | Acryl polymer A | 100 | 100 | 100 | 100 | 100 | 100 | 100 | 100 | 100 | 100 |
| Alkaline soluble polymer | Acryl polymer B | 100 | 100 | 100 | 100 | 100 | 100 | 100 | 100 | 100 | 100 |
| Colorant 2 | TiO2 particle | 20 | 180 | 260 | 260 | 320 | 400 | 320 | 600 | 1120 | 2500 |
| (White pigment) | dispersion | | | | | | | | | | |
| | (Tokushiki) | | | | | | | | | | |
| Colorant 2. | TiO2 particle | | | | | | | | | | |
| (White pigment) | dispersion A | | | | | | | | | | |
| | (Toyocolor) | | | | | | | | | | |
| Colorant 3 | Black pigment 1 | | | | | | | | | | |
| (Black pigment) | (Toyocolor) | | | | | | | | | | |
| Colorant 1 (Black dye containing | Dye A | 4 | 1.5 | 3 | 2 | 1.2 | 1.4 | 1.3 | 1.26 | 1.3 | 1.3 |
| dye A, B and C; Hayashibara ) | Dve B | 3.4 | 1.0 | 1 | 0.8 | 0.6 | 0.6 | 0.9 | 0.9 | 0.9 | 1.1 |
| | Ove C | 5 | 1.2 | 1.2 | 1 | 0.8 | 0.8 | 0.8 | 0.8 | 0.8 | 0.8 |
| Photo-radical Initiator A | NCI-831 | 4 | 4 | 4 | 4 | 4 | 4 | 4 | 5.2 | 7.4 | 13 |
| Photo-radical Initiator B | Omnirad 784 | 6.2 | 6.2 | 6.2 | 6.2 | 6.2 | 6.2 | 6.2 | 8 | 11.4 | 20.6 |
| Thiol containing polyfunctional | KarenzMT PE-1 | 70 | 100 | 70 | 70 | 70 | 70 | 70 | 70 | 70 | 70 |
| chemical compound | | | | | | | | | | | |
| Fluorine containing surfactant | Fluorine containing | 0.18 | 0.18 | 0.18 | 0.18 | 0.18 | 0.18 | 0.18 | 0.34 | 0.48 | 0.85 |
| having crosslinking group | surfactant A (DIC) | | | | | | | | | | |

Comparative Examples 1-2: Preparation of Bank compositions The comparative bank compositions 1-2 are prepared in the same manner as described in working example 1 except for that the following materials as mentioned in table 3 are used instead of the materials used in working example 1. Here PGMEA solvent (not mentioned in the table 3) is added so that the composition contains 35 wt % of total solid contents and 65 wt % of solvent based on the total weight of the composition after addting the solvent as same to working example 1.

TABLE 3

| | | Comparative | |
|---|---|---|---|
| | | examples | |
| | | 1 | 2 |
| Chemical compound containing | A-DPH | 133.3 | 133.3 |
| at least two (meth)acryloyloxy | (Shin-Nakamura) | | |
| groups (Monomer) | | | |
| Alkaline soluble polymer | Acryl polymer A | 33.3 | 33.3 |
| Alkaline soluble polymer | Acryl polymer B | 100 | 100 |
| Colorant 2 | TiO2 particle | | 448 |
| (White pigment) | dispersion | | |
| | (Tokushiki) | | |
| Colorant 2 | TiO2 particle | 448 | |
| (White pigment) | dispersion B | | |
| | (Toyocolor) | | |
| Colorant 3 | UB-1 | 2.1 | 5.5 |
| (Black pigment) | | | |
| Colorant 1 (Black dye containing | Dye A | | |
| dye A, B and C; Hayashibara) | Dye B | | |
| | Dye C | | |
| Photo-radical Initiator A | NCI-831 | 4.0 | 4.0 |
| Photo-radical Initiator 8 | Omnirad 784 | | |
| Thiol containing polyfunctional | KarenzMT PE-1 | | |
| chemical compound | | | |
| Fluorine containing surfactant | Fluorine containing | 1.2 | 1.2 |
| having crosslinking group | surfactant B (DIC) | | |

### Working Examples 21: Fabrication of Cured Films (Cured Compositions)

For OD and reflection measurements of samples, film samples 1 to 20 are fabricated by using the compositions from W.E. 1 to W.E. 20.

Firstly, obtained bank compositions from W.E.1 to W.E.20 are each separately coated onto a grass substrate by spin coater (MS-A100, MIKASA). Then coated glass substrates 1 to 20 are pre-baked on the hot-plate (HHP-411V, AS ONE) at 90° C. for 120 sec. to obtain 10 μm average layer thickness of pre-baked composition coated on the substrate. Then the whole surface of the samples is exposured to light by ghi-line exposure machine for photoliso graphy (NES2W-ghi06, Nikon) at 30 mJ/cm² without using any pattern mask and Post exposure baking process is applied for the samples withusing the hot-plate (HHP-411V, AS ONE) at 120° C. for 90 sec.

Then, post exposure baked samples 1 to 11 are developed by 0.03 wt % KOHaq used as a developer for 180 sec.

Finally, Post exposure baking process is applied for the samples withusing the hot-plate (HHP-411V, AS ONE) at 120° C. for 30 min to promote curing.

Then baked samples are cooled down to the room temperature. Finally, film samples 1 to 20 are obtained.

### Comparative Example 3: Fabrication of Cured Films (Cured Compositions)

Comparative cured film samples 1 and 2 are fabricated in the same manner as described in working example 21 except for that the compositions from comparative examples 1-2 are used and obtained average layer thickness of pre-baked composition of the comparative cured film samples 1 and 2 is 17 μm (sample 1) and 9 μm (sample 2) each respectively. Then, comparative samples 1 and 2 are obtained.

Working Examples 22: measurement of optical density (OD) values The transmission spectrum of the obtained film samples 1 to 20 from working example 21 is measured by spectrophotometric colorimeter (CM-5 Konica Minolta). And the OD values at 460, 540, 630 nm of each samples are calculated.

Working Examples 23: measurement of reflectance of the samples The reflection spectrum of each obtained film samples from working example 21 is measured by spectrophotometric colorimeter (CM-5 Konica Minolta). And the average reflectance in the range from 460 to 630 nm of each samples is separately calculated.

Table 4 shows the measurement results of W.E.13 and W.E. 14.

TABLE 4

| | Samples | 1 | 2 | 3 | 4 | 5 | 6 | 7 | 8 | 9 | 10 |
|---|---|---|---|---|---|---|---|---|---|---|---|
| Exposure Value | mJ/cm2 | 30 | 30 | 30 | 30 | 30 | 30 | 30 | 30 | 30 | 30 |
| OD | at 460 nm | 2.05 | 2.15 | 2.01 | 1.77 | 3.7 | 2.0 | 2.6 | 2.0 | 1.5 | 1.5 |
| | at 540 nm | 2.23 | 2.35 | 2.21 | 1.99 | 3.4 | 2.2 | 2.5 | 2.0 | 1.7 | 1.6 |
| | at 630 nm | 2.24 | 2.36 | 2.23 | 2.03 | 2.8 | 2.3 | 2.6 | 2.2 | 1.9 | 1.7 |
| Reflectivity % | Ave. 450-650 nm | 4.7 | 5.2 | 5.7 | 5.7 | 9.1 | 13.3 | 9.5 | 7.5 | 5.4 | 5.2 |
| | Samples | 11 | 12 | 13 | 14 | 15 | 16 | 17 | 18 | 19 | 20 |
| Exposure Value | m/cm2 | 30 | 30 | 30 | 30 | 30 | 30 | 30 | 30 | 30 | 30 |
| OD | at 460 nm | 1.8 | 2.0 | 2.2 | 2.0 | 1.9 | 2.0 | 2.0 | 2.0 | 2.0 | 2.1 |
| | at 540 nm | 1.8 | 2.0 | 2.2 | 2.0 | 1.5 | 1.8 | 2.3 | 2.0 | 2.0 | 2.1 |
| | at 630 nm | 1.9 | 2.0 | 2.9 | 2.4 | 2.3 | 2.1 | 2.0 | 1.9 | 1.8 | 2.0 |
| Reflectivity % | Ave. 450-650 nm | 5.2 | 22.7 | 21.5 | 25.0 | 32.8 | 33.2 | 29.6 | 35.0 | 39.0 | 40.0 |

Concerning the comparative cured film samples 1 and 2, reflectivity at 550 nm is 46.5 and 33.3, and OD value (average in the range from 400-650 nm) is 1.7 and 1.9 each respectively.

Working Examples 24: fabrication of patterned films (bank) Cured film samples 3′, 6′, 11′, 12′, 13′, 14′, 16′ to 20′ are fabricated by using the compositions from working examples 3, 6, 11, 12, 13, 14, 16-20.

Firstly, obtained bank compositions from working examples 3, 6, 11, 12, 13, 14, 16-20.are each separately coated onto a grass substrate by spin coater (MS-A100, MIKASA). Then coated glass substrates 1 to 20 are pre-baked on the hot-plate (HHP-411V, AS ONE) at 90° C. for 120 sec. to obtain 10 μm average layer thickness of pre-baked composition coated on the substrate.

Then the samples are exposured to light by ghi-line exposure machine for photoliso graphy (NES2W-ghi06, Nikon) at exposure value (mJ/cm²) mentioned on talbe 5 with using a pattern mask 1 having 15.0 μm line width and 150.0 μm space for samples 3′, 6′, 11′, 13′, 14′, 16′ to 20′.

For sample 12′, a pattern mask 2 having 7.5 μm line width and 157.5 μm space is used instead of the pattern mask having 15.0 μm line width and 150.0 μm space.

Then, obtained samples are developed by 0.03 wt % KOHaq used as a developer for 100 sec and rinsed by ultrapure water.

Finally, Post exposure baking process is applied for the samples withusing the hot-plate (HHP-411V, AS ONE) at 120° C. for 30 min.

Then baked samples are cooled down to the room temperature. Finally, patterned samples 3′, 6′, 11′, 12′, 13′, 14′, 16′ to 20′ are obtained.

Working Examples 25: evaluation of pattern structure Pattern structure of the obtained patterned samples 3′, 6′, 11′, 12′, 13′, 14′, 16′ to 20′ from working example 24 is measured by an optical microscope (MX61A, OLYMPUS) and SEM (JSM-7100, JEOL).

Namely, a development residue in the unexposed area of the samples and the surface roughness of the patterned structure of the samples are measured by optical microscope (MX61A, OLYMPUS) and SEM (JSM-7100, JEOL).

And, by using SEM, the maximum patteren line width and the minimum patteren line width of the obtained patterned samples 3′, 6′, 11′, 12′, 13′, 14′, 16′ to 20′ are measured.

If development residue is observed in the unexposed area, it is indicated as “Y” in below table 5 and if no development residue is observed in the unexposed area, it is indicated as “N” in below table 5.

“OK” in table 5 for the obtained patterned samples 3′, 6′, 11′,13′, 14′, 16′ to 20′ (mask 1 is used) means: the maximum line width and the minimum line width of a sample is in the range from 28-32 μm and the difference of the maximum line width and the minimum line width of a sample is 1 μm or less.

“OK” in table 5 for the obtained patterned sample 12′ (mask 2 is used) means: the maximum line width and the minimum line width of a sample is in the range from 15-18 μm and the difference of the maximum line width and the minimum line width of a sample is 1 μm or less.

If sample does not satisfy the above condition, then “NG” is indicated in table 5.

About the surface roughness of the patterned structure of the samples, “A” means that the surface roughness of the upper side or the side surface of the patterned structure of the samples are smooth and structure is fine.

“B” means that the surface roughness of the upper side or the side surface of the patterned structure of the samples are a little rough but the patterned structure is maintained.

“C” means that the surface roughness of the upper side or the side surface of the patterned structure of the samples are rough and the patterned structure is more damaged than “B”.

Table 5 shows the results of W.E. 25.

TABLE 5

| | | Samples | | | | | | | | | | |
|---|---|---|---|---|---|---|---|---|---|---|---|---|
| | | 3′ | 6′ | 11′ | 12′ | 13′ | 14′ | 16′ | 17′ | 18′ | 19′ | 20′ |
| | | Residue | | | | | | | | | | |
| | | N | Y | Y | N | N | N | N | N | N | N | N |
| | | Patterning | | | | | | | | | | |
| | | OK | NG | OK | OK | OK | NG | OK | OK | OK | OK | OK |
| Mask 1 | Max. line width | 14.9 | — | 29.2 | | 30.0 | 28.6 | 28.8 | 28.9 | 30.1 | 31.3 | 31.3 |
| | (μm) | | | | | | | | | | | |
| | Min. line width | 14.9 | — | 29.6 | | 29.1 | 26.3 | 27.1 | 28.0 | 29.2 | 31.3 | 31.3 |
| | (μm) | | | | | | | | | | | |
| Mask 2 | Max. line width | | | | 17.3 | | | | | | | |
| | (μm) | | | | | | | | | | | |
| | Min. line width | | | | 16.3 | | | | | | | |
| | (μm) | | | | | | | | | | | |
| Surface | the upper side | A | | A | A | A | A | A | A | A | A | A |
| Roughness | the side surface | B | | A | A | A | A | B | B | B | C | C |

1. A composition, comprising:
an alkaline-soluble polymer that includes an ethylenic double bond; and
a first colorant.

2. The composition of claim 1, wherein the composition is a photocurable composition and does not include any polysiloxane.

3. The composition of claim 1, wherein the solid acid value of the alkaline-soluble polymer is in the range from 30 to 160 mgKOH/g.

4. The composition of claim 1, further comprising a thiol containing polyfunctional chemical compound.

5. The composition of claim 1, further comprising a chemical compound containing at least two (meth)acryloyloxy groups.

6. The composition of claim 1, further comprising a surfactant.

7. The composition of claim 1, wherein the first colorant is selected from the group consisting of an organic black pigment, an inorganic black pigment, an organic white pigment and inorganic white pigment.

8. The composition of claim 1, further comprising a second colorant different from the first colorant.

9. The composition of claim 8, further comprising third colorant different from the first and second colorants.

10. The composition of claim 1, wherein the first colorant is included in a range from 0.1 wt. % to 50 wt % based on the total weight of the alkaline-soluble polymer of the composition.

11. The composition of claim 8, wherein the second colorant is included in a range from 1 wt % to 400 wt % based on the total weight of the alkaline-soluble polymer of the composition.

12. The composition of claim 8 wherein a ratio of the first colorant to the second colorant is in a range from 0.0001 to 50.

13. A method for fabricating a cured layer comprising at least the following steps;
(Xi) providing the composition of claim 1 onto a layer or onto a substrate to form a coated layer; and
(Xii) baking a coated layer to obtain a cured layer.

14. A layer comprising:
a polymer derived or derivable from an alkaline-soluble polymer containing an ethylenic double bond; and
a colorant.

15. The layer of claim 14, wherein the layer satisfies at least one of the following values:
an Optical Dencity (OD) value of the layer at 10 μm layer thickness at light wavelength 460 nm is in the range from 1.0 to 4.0,
an OD value of the layer at 10 μm layer thickness at light wavelength 540 nm is in the range from 1.0 to 4.0,
an OD value of the layer at 10 μm layer thickness at light wavelength 630 nm is in the range from 1.0 to 3.0.

16. The layer of claim 14, wherein an average reflection value of the layer at 10 μm layer
thickness in the light wavelength range from 450-650 nm is in the range from 20 to70%.

17. A light converting device comprising at least the layer of claim 14.

18. An optical device comprising at least the layer of claim 14.
